(19) United States
(12) Patent Application Publication
(10) Pub. No.: US 2003/0197196 A1
(43) Pub. Date: Oct. 23, 2003

(54) Methods of gas switching in rapid thermal process for improving the reliability of the insulation layer

(75) Inventors: Chee-Wee Liu, Taipei (TW); Min-Hung Lee, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: National Taiwan University, Taipei (TW)

(21) Appl. No.: 10/120,970

(22) Filed: Apr. 11, 2002

(51) Int. Cl. H01L 31/0328

(52) U.S. Cl. 257/200

(57) ABSTRACT

A method of gas switching in a rapid thermal process for improving the reliability of an insulation layer is disclosed. The method includes steps of providing a silicon substrate; introducing a process gas; rapidly heating said silicon substrate to a process temperature for producing an insulation layer on said silicon substrate; and immediately stopping introducing said process gas in a moment of switching to reduce said process temperature for preventing said silicon substrate from producing an insulation layer.

### FIELD OF THE INVENTION

The present invention is related to a method for improving the reliability of a insulation layer, and more particularly to a method of gas switching in a rapid thermal process for improving the reliability of the insulation layer.

### BACKGROUND OF THE INVENTION

A rapid thermal process is an important process in 8″ integrated circuit fabrication, i.e. source/drain annealing and silicide formation, and this kind of process must be applied extensively in 12″ ultra large scale integrated circuit fabrication in the future, i.e. the rapid thermal oxide, the polysilicon and the SiGe(C) epitaxy formation. According to International Technology Roadmap for Semiconductors (ITRS) in 1999, the thickness of the gate oxide layer of a deep sub-micron device will be thinner than 1 nm in 2012 and the thermal budget will be reduced effectively by the rapid thermal process. The ramp-up rate of the rapid thermal process could be controlled through changing the power of lamp and be ranged from 50 to 400° C./sec. However, the ramp-down process could only be executed by the nature force and the rate is ranged from 60 to 90° C./sec. During the slow ramp-down cycle, an inferior oxide layer may be formed.

Hence, the present invention is attempted to improve the prior art and provides a method of gas switching in a rapid thermal process for improving the reliability of the insulation layer.

### SUMMARY OF THE INVENTION

It is one object of the present invention to provide a method for improving the stability of the insulation layer.

It is another object of the present invention to provide a method of gas switching in a rapid thermal process for improving the reliability of the insulation layer and reducing the cost of fabricating a deep sub-micron device

According to the present invention, a method of gas switching in rapid thermal process for improving the reliability of the insulation layer, comprising steps of (a) providing a silicon substrate; (b) introducing a process gas; (c) rapidly heating said silicon substrate to a process temperature for producing an insulation layer on said silicon substrate; and (d) immediately stopping introducing said process gas in a moment of switching to reduce said process temperature for preventing said silicon substrate from producing an insulation layer during the cooling cycle.

Certainly, the silicon substrate can be one of P-type and N-type semiconductor substrates.

Certainly, the silicon substrate can be one selected from a group consisting of single crystalline, polycrystalline and amorphous silicon substrates, silicon-germanium substrates and semiconductor substrates.

Preferably, the step (a) further comprises steps of (a1) dipping said silicon substrate to remove a native oxide; and (a2) loading said silicon substrate to a producing system and increasing temperature up to 1000° C. to pre-bake said silicon substrate for removing a top oxide layer of said silicon substrate.

Certainly, the step (b) can be one selected from a group consisting of oxygen, SiH₄, SiCl₂H₂, GeH₄, SiCH₆, N₂O, NO, TEOS(tetraethoxysilane) and a mixture gas thereof.

Preferably, the step (b) is operated at a process pressure ranged from 1 mbar to 1000 mbar.

Preferably, the process temperature of said step (c) is ranged from 500° C. to 1000° C.

Certainly, the process temperature of said step (c) can be controlled in a stable temperature up to 10 days.

Preferably, said step (d) further comprises a step of (d1) introducing a gas to purge said process reactor.

Certainly, the gas of said step (d1) can be an inert gas.

Preferably, the inert gas is one selected from a group consisting of nitrogen, argon, helium and a mixed gas.

Preferably, the insulation layer of said step (c) is produced by one selected from a group consisting of furnace oxidation, rapid thermal oxidation, and chemical vapor deposition.

Preferably, the insulation layer of said step (c) is one selected from a group consisting of silicon dioxide, silicon nitride, oxynitride and a material having a high-dielectric constant.

Preferably, the layer of said step (c) is one selected from a group consisting of a silicon-germanium epitaxy film, a polycrystalline silicon film, a polycrystalline silicon-germanium film and a silicon-germanium-carbon epitaxy film.

Preferably, the insulation layer of said step (c) has a thickness ranged from 0.3 nm to 10 um.

Preferably, the step (d) further comprises a step of (d2) introducing a gas, one selected from a group consisting of hydrogen, deuterium, nitrogen and a mixture gas thereof for annealing.

Now the foregoing and other features and advantages of the present invention will be more clearly understood through the following descriptions with reference to the drawings, wherein:

### BRIEF DESCRIPTION OF THE DRAWINGS

FIG. 1 depicts a relationship between the flow rate of oxygen and temperatures of an overall oxidation cycle and a ramp-up oxidation cycle;

FIGS. 2(a)-2(c) illustrate a relationship between the change of current and the stress time of two oxidation cycles at temperature 1000° C.;

FIGS. 3(a)-3(b) illustrate relationships between the change of current and the stress time of two oxidation cycles at temperature 900° C.; and

FIGS. 4(a)-4(b) illustrate a relationship between the change of current and the stress time of the device of the overall oxidation compared with that of the device without the ramp-down oxidation cycle.

### DETAILED DESCRIPTION OF THE PREFERRED EMBODIMENT

A preferred embodiment of the method for improving the stability of the insulation layer of the present invention includes several steps. First, a P-type silicon wafer is dipped into the hydrofluoric acid (HF) for removing the native oxide on the surface of the P-type silicon wafer and then the P-type silicon wafer is loaded to a process reactor. Hydrogen is introduced into the process reactor, the temperature of the formation system is increased up to 1000° C. and the P-type silicon wafer is pre-baked at a pre-baking pressure 250 mbar for two minutes. After introducing nitrogen into the process reactor for ten minutes to purge the situation of the process reactor, oxygen or a mixed gas of oxygen and nitrogen is introduced into the process reactor and a rapid ramp-up oxidation process is executed at a pressure 250 mbar, wherein the temperature of the wafer is increased up to the top set value in ten seconds and then decreased immediately. Oxygen is merely introduced during the ramp-up oxidation cycle. While the temperature starts to be decreased from the peak value, the introduced gas is switched from oxygen into nitrogen. Finally, nitrogen is introduced into the process reactor for ten minutes to purge the situation of the process reactor, and then hydrogen and nitrogen are introduced into the process reactor to anneal the P-type silicon wafer at a pressure 250 mbar for ten minutes respectively, wherein the reacting temperature is increased up to 900° C.

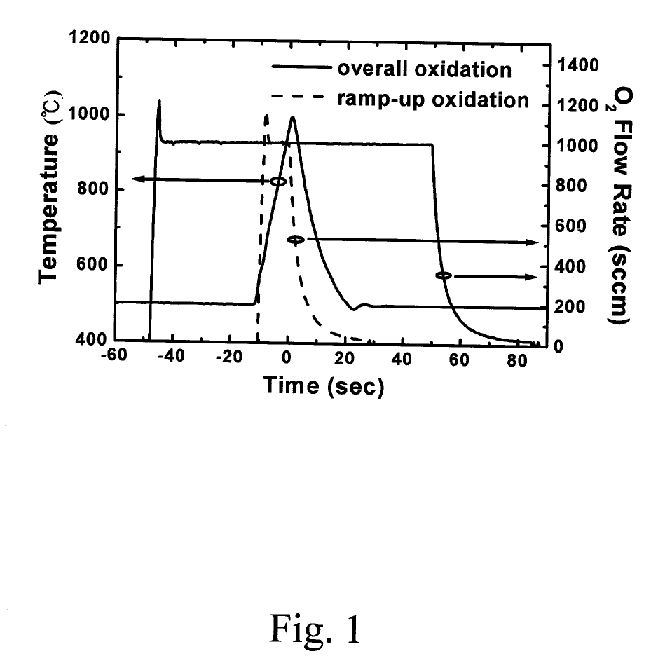

For an NMOS diode, the ultra-thin gate oxide layer of the NMOS diode is produced by using a rapid thermal oxidation (RTO) process integrated with a spike ramp process. FIG. 1 depicts a relationship between the flow rate of oxygen and temperatures of an overall oxidation and a ramp-up oxidation. The mechanism of the oxide layer growth includes steps of diffusing of oxygen into an interface of silicon and silicon dioxide (Si/SiO₂) and then reacting with silicon to form a silicon dioxide. As shown in FIG. 1, the ramp-down rate of the temperature is slower than the ramp-up rate of the temperature and the ramp-up temperature is adjusted through controlling the power of the lamp for obtaining a ramp-up temperature curve. The formed oxide layer is near closely to the interface of Si/SiO₂, the quality of the formed oxide layer is influenced easily during the period of ramp-down temperature. Hence, the period of the oxidation is determined by switching the introduced gas. When the introduced gas is switched from oxygen at 1000 sccm into nitrogen at 1000 sccm, the oxidation is terminated. The solid line of FIG. 1 illustrates a prior art to produce an oxide layer. Oxygen is introduced from the start of increasing the temperature to the end of decreasing the temperature during the overall oxidation cycle. The period of the oxidation is merely responsive to the change of the temperature. The dotted line of FIG. 1 illustrates the present invention in producing the oxide layer. Only oxygen is introduced during the period of the ramp-up oxidation cycle. The introduced gas is switched into nitrogen while the temperature is increased to the top set value and started to be decreased. The thickness of the oxide layer can be measured by an ellipsometry. The resistance value of the P-type silicon wafer is ranged from 1 to 10 Ω-cm. An electrode of the NMOS diode is formed of aluminum and the area of the electrode is 3×10⁻⁴cm². The reliability of the oxide layer is analyzed by HP 4156A to execute a constant voltage stress (CVS) and a constant current stress (CCS) measurement.

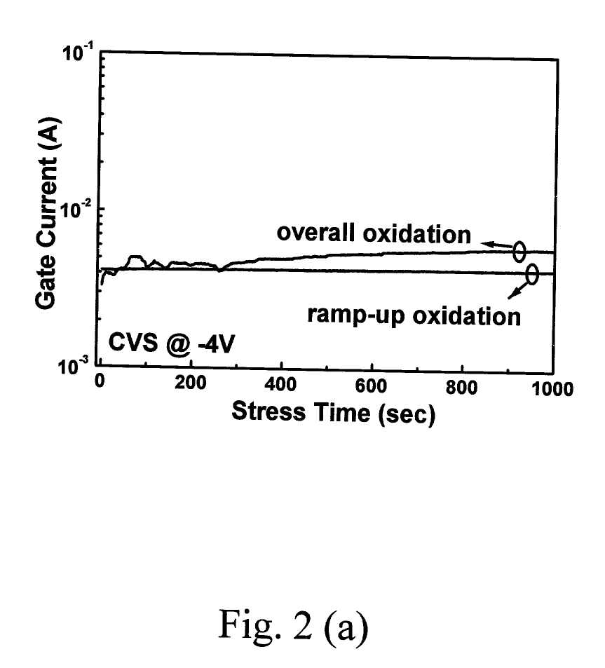

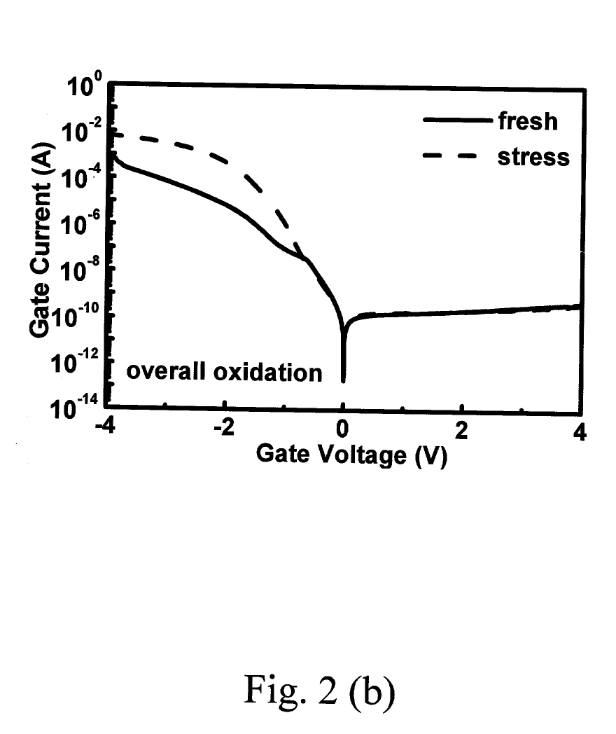

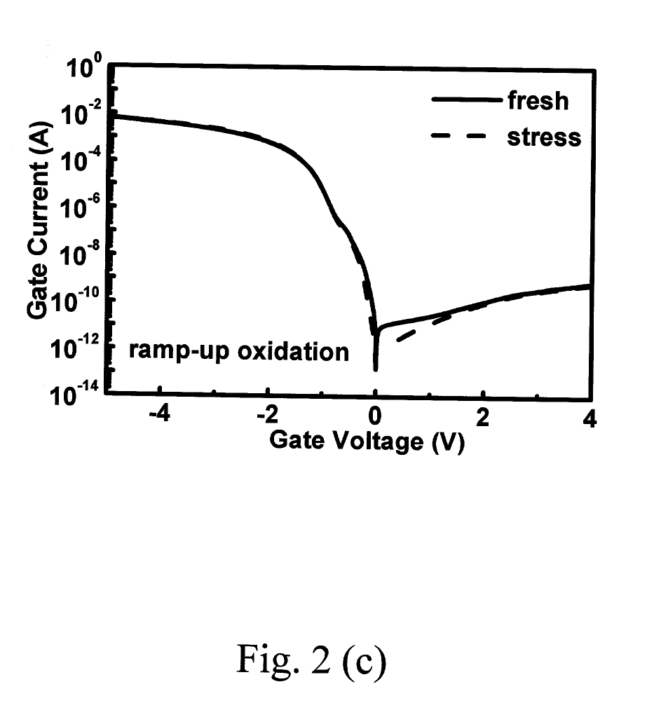

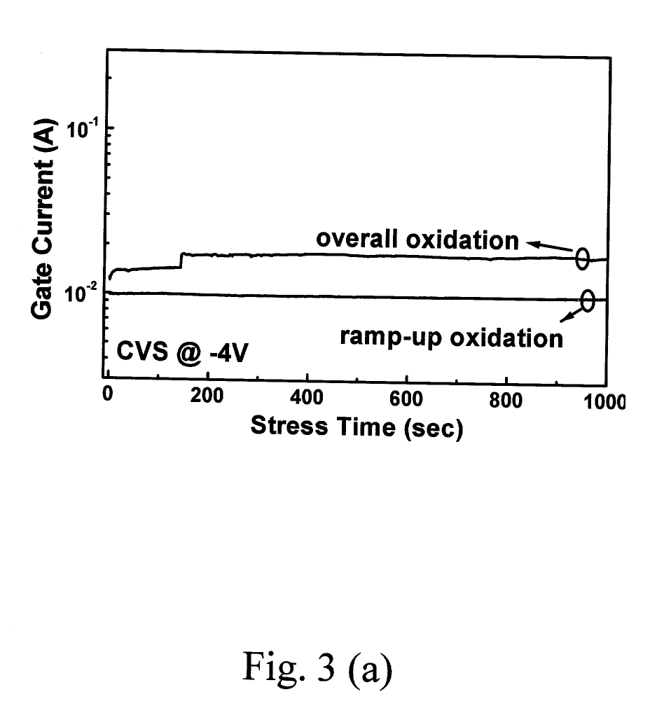

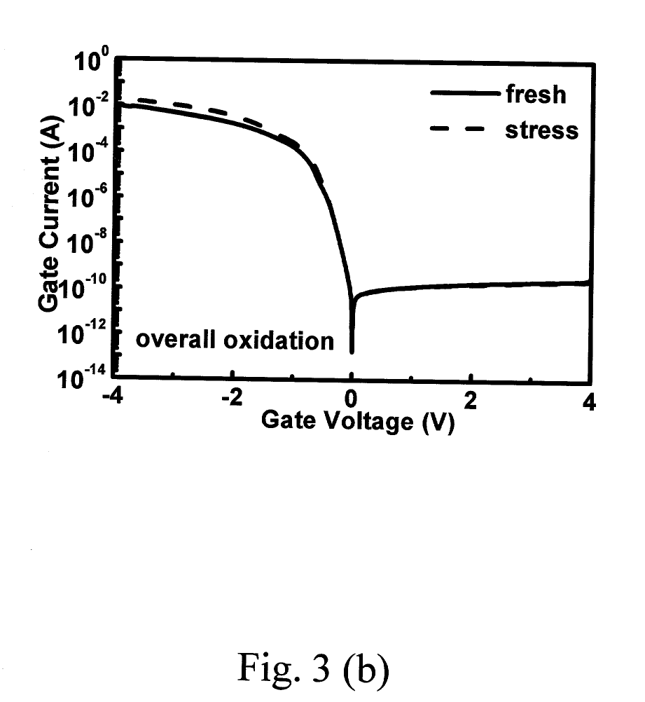

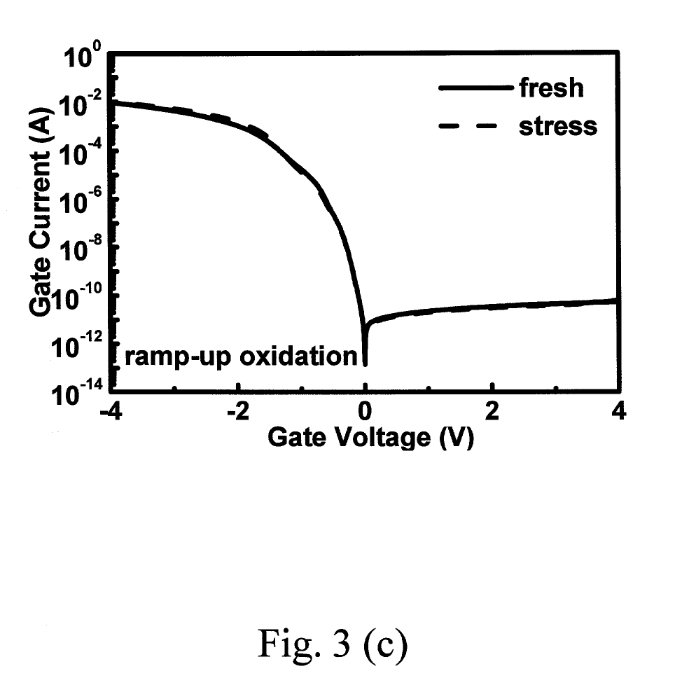

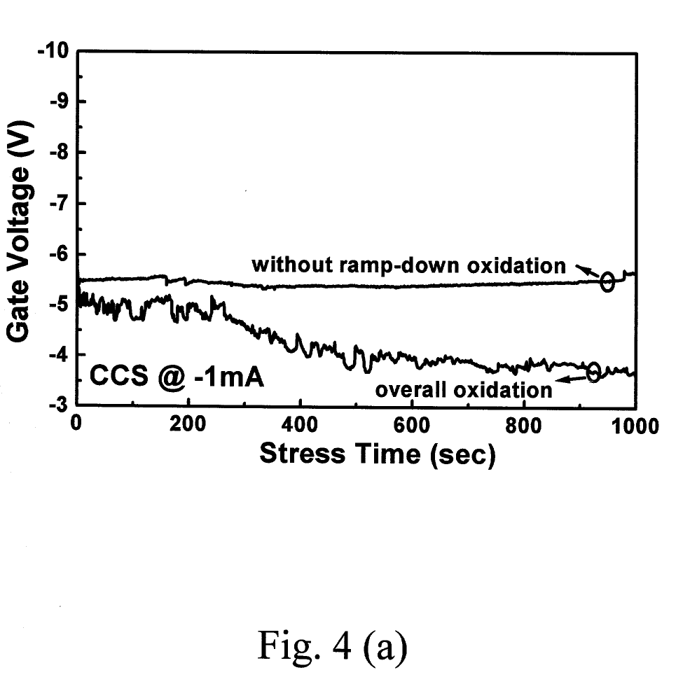

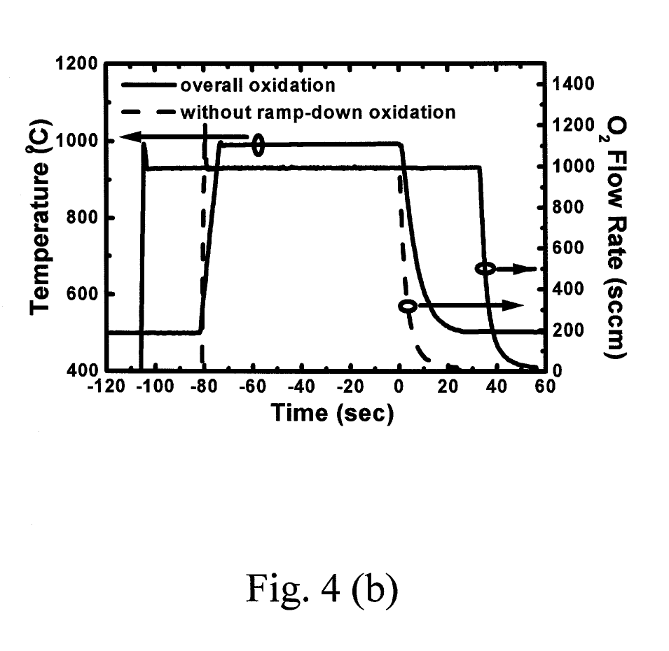

While the NMOS is produced by executing a spike ramp thermal oxidation process, the temperature of the condition is increased up to the peak value and then decreased immediately, wherein the oxide layer is formed at temperatures ranged from 800° C. to 1000° C. FIG. 2(a) illustrates a relationship between the change of current and the stress time of two oxidation cycles at peak temperature 1000° C. The thickness of the oxide layer of the device is about 1.2 nm. The gate current of the device of the ramp-up oxidation doesn't change significantly after the device with the ramp-up oxidation cycle is worked by a voltage stress. As shown in FIG. 2(c), the dotted line illustrates a relationship between the gate voltage and the gate current of the ramp-up oxidation device after CVS at −4V for 1000 seconds and the solid line illustrates a relationship between the gate voltage and the gate current of the ramp-up oxidation device without CVS. The relative curve of the stressed one is almost the same as that of the fresh one. However, the dotted line of FIG. 2(b) illustrates a relationship between the gate voltage and the gate current of the overall oxidation device after CVS at −4V for 1000 seconds and the solid line illustrates a relationship between the gate voltage and the gate current of the overall oxidation device without CVS. The current crossing the accumulated zone increases significantly after CVS at −4V for 1000 seconds and it means that the device is deteriorated. Even though the peak value of the temperature in the research of the temperature-switching effect is changed, the similar result is obtained. FIG. 3(a) illustrates a relationship between the change of current and the stress time of two oxidation cycles at temperature 900° C. The thickness of the oxide layer of the device is about 0.9 nm. For the conventional rapid thermal oxidation process, the oxide layer is formed at 1000° C. for 70 seconds. One process is introduced with oxygen in the overall process. Another process is introduced with oxygen but switched from oxygen into nitrogen while the temperature starts to decrease for preventing from oxidation during the ramp-down cycle. FIG. 4(b) illustrates a relationship between the change of temperature and the flow rate of oxygen. FIG. 4(a) illustrates the change of the current and the stress time of the device having thickness of 5.2 nm by CCS at −1 mA for 1000 seconds. The voltage change of the device of the overall oxidation is larger than that of the device without the ramp-down oxidation. It means that the device of the overall oxidation deteriorates seriously. Hence, the method of gas switching for improving the reliability of the insulation layer is not only working in a spike ramp thermal oxidation process but also in a conventional rapid thermal oxidation process.

Although the present invention has been described and illustrated in detail, it is to be clearly understood that the same is by the way of illustration and example only and is not to be taken by way of limitation, the spirit and scope of the present invention being limited only by the terms of the appended claims.

What is claimed is:

1. A method of gas switching in a rapid thermal process for improving a reliability of the insulation layer, comprising steps of:
(a) providing a silicon substrate;
(b) introducing a process gas;
(c) rapidly heating said silicon substrate to a process temperature for producing an insulation layer on said silicon substrate; and
(d) immediately stopping introducing said process gas in a moment of switching to reduce said process temperature for preventing said silicon substrate from producing an insulation layer during the cooling cycle.

2. The method of gas switching in a rapid thermal process according to claim 1, wherein said silicon substrate is one of P-type and N-type silicon substrates.

3. The method of gas switching in a rapid thermal process according to claim 1, wherein said silicon substrate is one selected from a group consisting of single crystalline, polycrystalline and amorphous silicon substrates, silicon-germanium substrates and semiconductor substrates.

4. The method of gas switching in a rapid thermal process according to claim 1, wherein said step (a) further comprises steps of:
(a1) dipping said silicon substrate to remove a native oxide; and
(a2) loading said silicon substrate to a producing system and increasing temperature up to 1000° C. to pre-bake said silicon substrate for removing a top oxide layer of said silicon substrate.

5. The method of gas switching in a rapid thermal process according to claim 1, wherein said reacting gas of said step (b) is one selected from a group consisting of oxygen, SiH₄, SiCl₂H₂, GeH₄, SiCH₆, N₂O, NO, TEOS(tetraethoxysilane) and a mixture gas thereof.

6. The method of gas switching in a rapid thermal process according to claim 1, wherein said step (b) is operated at a process pressure ranged from 1 mbar to 1000 mbar.

7. The method of gas switching in a rapid thermal process according to claim 1, wherein said process temperature of said step (c) is ranged from 500° C. to 1000 ° C.

8. The method of gas switching in a rapid thermal process according to claim 1, wherein said process temperature of said step (c) is controlled in a stable temperature up to 10 days.

9. The method of gas switching in a rapid thermal process according to claim 1, wherein said step (d) further comprises a step of (d1) introducing a gas to purge said process reactor.

10. The method of gas switching in a rapid thermal process according to claim 9, wherein said gas of said step (d1) is an inert gas.

11. The method of gas switching in a rapid thermal process according to claim 10, wherein said inert gas is one selected from a group consisting of nitrogen, argon, helium and a mixed gas.

12. The method of gas switching in a rapid thermal process according to claim 1, wherein said insulation layer of said step (c) is produced by one selected from a group consisting of furnace oxidation, rapid thermal oxidation, and chemical vapor deposition.

13. The method of gas switching in a rapid thermal process according to claim 1, wherein said insulation layer of said step (c) is one selected from a group consisting of silicon dioxide, silicon nitride, oxynitride and a material having a high-dielectric constant.

14. The method of gas switching in a rapid thermal process according to claim 1, wherein said layer of said step (c) is one selected from a group consisting of a silicon-germanium epitaxy film, a polycrystalline silicon film, a polycrystalline silicon-germanium film and a silicon-germanium-carbon epitaxy film.

15. The method of gas switching in a rapid thermal process according to claim 1, wherein said insulation layer of said step (c) has a thickness ranged from 0.3 nm to 10 um.

16. The method of gas switching in a rapid thermal process according to claim 1, wherein said step (d) further comprises a step of (d2) introducing a gas, one selected from a group consisting of hydrogen, deuterium, nitrogen and a mixture gas thereof for annealing.
